(19) United States
(12) Patent Application Publication
(10) Pub. No.: US 2012/0138350 A1
(43) Pub. Date: Jun. 7, 2012

(54) ELECTRONIC COMPONENT ALIGNING DEVICE, ELECTRONIC COMPONENT PACKAGING BODY, AND ELECTRONIC COMPONENT MOUNTING BOARD.

(75) Inventors: Pum San CHAE, Anyang (KR); Doo Young KIM, Yongin (KR); Kang Heon HUR, Seongnam (KR); Hong Yeon CHO, Suwon (KR)

(73) Assignee: SAMSUNG ELECTRO-MECHANICS CO., LTD.

(21) Appl. No.: 13/309,263

(22) Filed: Dec. 1, 2011

(30) Foreign Application Priority Data
Dec. 2, 2010 (KR) 10-2010-0122304

(51) Int. Cl. H05K 1/16; H05K 13/04; B65G 47/24

(52) U.S. Cl. 174/260; 198/381; 29/738

(57) ABSTRACT

There is provided a device for electronic components including: a tray provided with electronic components formed by stacking dielectric sheets on which inner conductors are formed; a transfer unit continuously transferring the electronic components moved from the tray; and a magnetic field providing unit providing a magnetic field to the electronic components moved from the transfer unit to align the inner conductors in a direction in which the magnetic field and magnetic resistance are reduced.

### CROSS-REFERENCE TO RELATED APPLICATIONS

This application claims the priority of Korean Patent Application No. 10-2010-0122304 filed on Dec. 2, 2010 in the Korean Intellectual Property Office, the disclosure of which is incorporated herein by reference.

### BACKGROUND OF THE INVENTION

1. Field of the Invention

The present invention relates to an electronic component aligning device, an electronic component packaging body, and an electronic component mounting board.

2. Description of the Related Art

Generally, when electronic components are mounted on a printed circuit board, it is impossible to recognize the directivity of inner conductors therein from the outward appearance thereof, such that the electronic components may be mounted on the printed circuit board independently of the directivity of the inner conductors.

In particular, when electronic components have a symmetrical appearance, they may have outwardly identical characteristics, regardless of the direction in which they are mounted on the printed circuit board. However, differences in the characteristics of electronic components occur due to the structural arrangement of inner conductors in the electronic components.

When electronic components are packaged in a packaging body, if the electronic components are packaged randomly, without discriminating between the directionality of the inner conductors thereof, it may be impossible to order the direction of the inner conductors when the electronic components in the packaging body are mounted on the printed circuit board.

Therefore, a limitation in which electronic components cannot be mounted on the printed circuit board in such a manner that the inner conductors thereof are arranged in the same direction.

In particular, when the inner conductors of electronic components are mounted in a direction parallel with the surface of the printed circuit board and voltage is applied thereto, a piezo effect may be generated in the inner conductors, such that vertical vibrations occur on the mounting surface of the printed circuit board.

This phenomena is referred to as acoustic noise and the vibrations caused thereby may be remarkably reduced by mounting electronic components on the printed circuit board in such a manner that the inner conductors thereof are vertically disposed with relation to the surface of the printed circuit board.

Research into mounting electronic components on the printed circuit board in such a manner that the inner conductors thereof are arranged vertically with relation to the printed circuit board has been required.

### SUMMARY OF THE INVENTION

An aspect of the present invention provides an electronic component aligning device for aligning the electronic components in order to mount the electronic components on a printed circuit board in the state in which inner conductors thereof are vertical to the printed circuit board.

Another aspect of the present invention provides an electronic component packaging body in which the electronic components aligned by using the electronic component aligning device are packaged.

Still another aspect of the present invention provides an electronic component mounting board on which the electronic components packaged in the electronic component packaging body are mounted on the printed circuit board in such a manner that the inner conductors thereof are arranged vertically to the printed circuit board.

According to an aspect of the present invention, there is provided an electronic component aligning device, including: a tray provided with electronic components formed thereon by stacking dielectric sheets on which inner conductors are formed; a transfer unit continuously transferring the electronic components moved from the tray; and a magnetic field providing unit providing a magnetic field to the electronic components moved from the transfer unit to align the inner conductors in a direction in which the magnetic field and magnetic resistance are reduced.

The magnetic field may flow between the inner conductors having the dielectric sheets interposed therebetween.

The inner conductors in the electronic components having passed through the magnetic field providing unit may be vertically disposed with relation to a moving direction of the transfer unit.

The magnetic field providing unit may includes a permanent magnet and a solenoid electromagnet.

The electronic components may have the same width W and height H.

The electronic component aligning device may further include a pickup transfer unit picking up the electronic components having passed through the magnetic field providing unit and transferring the electronic components from the transfer unit to an electronic component packaging body.

The electronic components may include a multilayer ceramic capacitor, an inductor, a line filter, or a varistor.

According to another aspect of the present invention, there is provided a packaging body for electronic components, including: electronic components formed by stacking dielectric sheets on which inner conductors are formed; and a packaging sheet formed with a receiving part in which the electronic components are received, wherein the inner conductors are vertically disposed with relation to the bottom surface of the receiving part by using the electronic components aligned by the electronic component aligning device of any one of claims 1 to 6.

The packaging body for electronic components may further include a packaging layer coupled with the packaging sheet and covering the electronic components.

According to another aspect of the present invention, there is provided an electronic component mounting board, including: electronic components formed by stacking dielectric sheets on which inner conductors are formed; and a printed circuit board on which the electronic components are mounted, wherein the inner conductors are vertically disposed with relation with a mounting surface of the printed circuit board by transferring the electronic components within the electronic component packaging body of claim 6, without changing the direction thereof.

The electronic components may be buried in the printed circuit board.

The electronic part may be provided in plural, each of the electronic components having the same width W and height T.

According to another aspect of the present invention, there is provided an electronic component mounting board, including: a plurality of electronic components each having the same width W and height T and formed by stacking dielectric sheets on which inner conductors are formed; and a printed circuit board having the electronic components thereon and having the inner conductors thereon in such a manner that all of the inner conductors in the plurality of electronic components are arranged in a vertical direction with relation to the mounting surface of the printed circuit board.

The electronic components may be buried in the printed circuit board.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a diagram schematically showing an electronic component aligning device according to an exemplary embodiment of the present invention;

FIG. 2 is a partially enlarged view schematically showing portion A of FIG. 1;

FIG. 3 is a diagram schematically showing that electronic components on a transfer unit of FIG. 1 are aligned by a magnetic field of a magnetic field providing unit;

FIG. 4 is a perspective view schematically showing that aligned electronic components are mounted in a packaging body according to an exemplary embodiment of the present invention;

FIG. 5 is a diagram schematically showing a roll-type packaging body according to another exemplary embodiment of the present invention;

FIG. 6 is a perspective view schematically showing an electronic component mounting board on which aligned electronic components are mounted according to an exemplary embodiment of the present invention; and

FIG. 7 is a cross sectional view schematically showing an electronic component mounting board on which aligned electronic components are buried and mounted according to another exemplary embodiment of the present invention.

### DETAILED DESCRIPTION OF THE PREFERRED EMBODIMENT

Exemplary embodiments of the present invention will now be described in detail with reference to the accompanying drawings. However, it should be noted that the spirit of the present invention is not limited to the embodiments set forth herein and those skilled in the art and understanding the present invention can easily accomplish retrogressive inventions or other embodiments included in the spirit of the present invention by the addition, modification, and removal of components within the same spirit, and those are to be construed as being included in the spirit of the present invention.

Further, throughout the drawings, the same or similar reference numerals will be used to designate the same components or like components having the same functions in the scope of the similar idea.

### Electronic Component Aligning Device

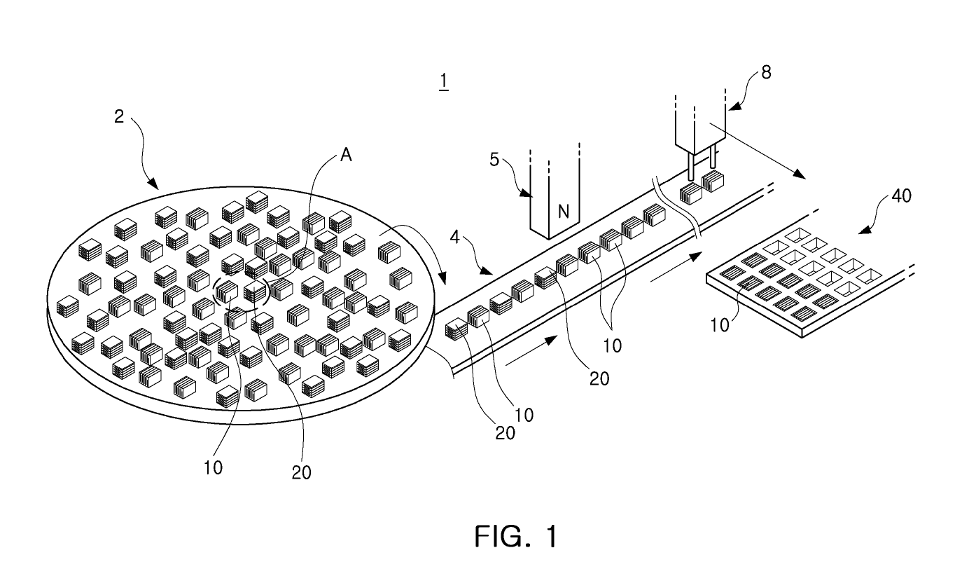

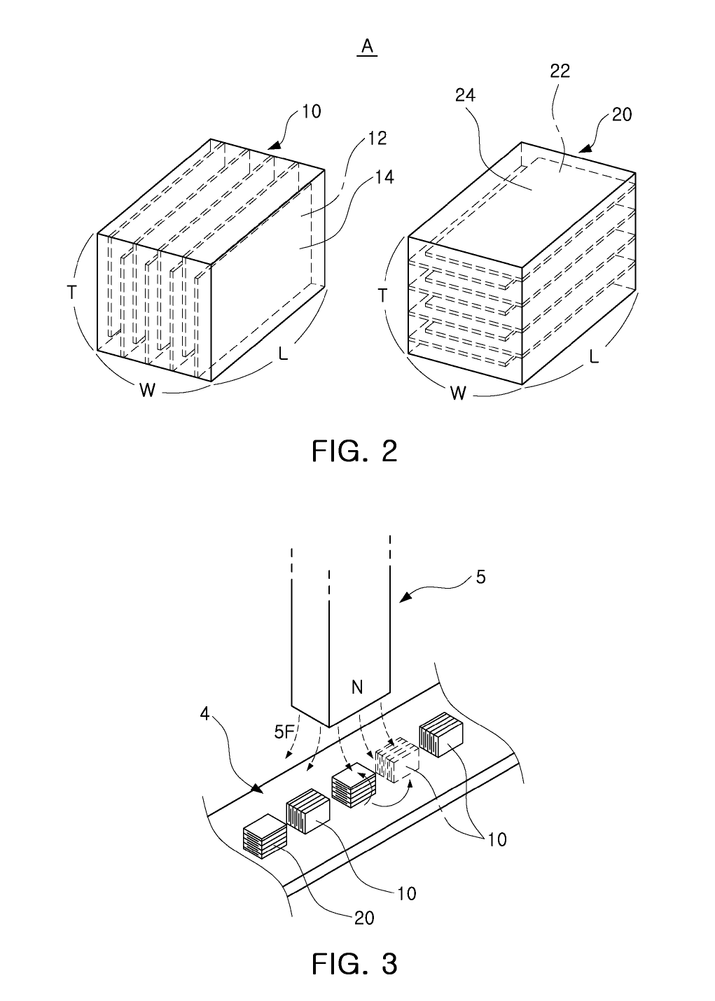

FIG. 1 is a diagram schematically showing an electronic component aligning device according to an exemplary embodiment of the present invention. FIG. 2 is a partially enlarged view schematically showing portion A of FIG. 1. FIG. 3 is a diagram schematically showing that electronic components on a transfer unit of FIG. 1 are aligned by a magnetic field of a magnetic field providing unit.

Referring to FIGS. 1 to 3, an electronic component aligning device 1 according to the exemplary embodiment of the present invention may be configured to include a tray 2, a transfer unit 4, and a magnetic field providing unit 5.

The tray 2 is provided with electronic components 10 and 20 formed by stacking dielectric sheets 14 and 24 on which inner conductors 12 and 22 are formed.

The electronic components 10 and 20 are chip-like components manufactured by stacking the inner conductors 12 and 22 having electrode patterns on the plurality of ceramic dielectric sheets 14 and 24 and may include a multilayer ceramic capacitor, an inductor, a line filter, a varistor, or the like.

As the electronic components 10 and 20, any components may be applied, as long as they include the inner conductors 12 and 22 having the dielectric sheets 14 and 24 interposed therebetween

Referring to FIG. 2, the electronic components 10 and 20 may be aligned on the tray 2 in the sate in which the inner conductors 12 and 22 thereof do not have directivity. The electronic components 10 and 20 may be aligned on the tray 2 in such a manner that the inner conductors 12 and 22 may be horizontally aligned or vertically aligned with relation to a width W direction thereof contacting the surface of the tray 2.

Here, in the electronic components 10 and 20, the electronic component in which the inner conductors 12 are vertically aligned with relation to the width W direction contacting the surface of the tray 2 is defined as the first electronic component 10. In addition, the electronic component in which the inner conductors 22 are horizontally aligned with relation to the width W direction contacting the surface of the tray 2 is defined as a second electronic component.

The first and second electronic components 10 and 20 have a rectangular parallelepiped shape having a width W, a height T, and a length L. From the appearances of the first and second electronic components 10 and 20, the directivity of the inner conductors 12 and 22 in the electronic components may not be recognized when the width W and the height T are the same.

The first and second electronic components 10 and 20 may be moved from the tray 2 to the transfer unit 4. Without being specifically limited, the movement to the transfer unit 4 may be automatically or manually made.

The transfer unit 4, which is a device such as a conveyor belt, may continuously transfer the first and second electronic components 10 and 20.

The magnetic field providing unit 5 provides a magnetic field 5F to the electronic components 10 and 20 transferred from the transfer unit 4, such that the inner conductors 12 and 22 may be aligned in a direction in which the magnetic field 5F and the magnetic resistance are reduced.

Similar to the first electronic component 10 and the second component 20, if the alignment states of the inner conductors 12 and 22 are different from each other, they are differently affected by the magnetic field 5F. As shown in FIG. 3, the magnetic field providing unit 5 may provide the magnetic field 5F in the direction vertical to the first electronic component 10 and the second electronic component 20 moved on the transfer unit 4.

The inner conductors 12 and 22 of the electronic components 10 and 20 in the magnetic field 5F are subjected to the magnetic resistance in such a manner as to be vertical to the magnetic field 5F. That is, the magnetic field 5F may flow between the inner conductors 12 and 22 having the dielectric sheets 14 and 24 interposed therebetween.

Therefore, the first electronic component 10 is moved on the transfer unit 4 in the state in which the inner conductors 12 thereof are vertical to the transfer unit 4, while the second electronic component 20 is aligned on the transfer unit 4 in such a manner that the inner conductors 22 are vertical to the transfer unit 4 so as to reduce magnetic resistance. Therefore, when the second electronic component 20 has passed through the magnetic field providing unit 5, the inner conductors thereof 20 are vertically disposed with relation to the moving direction of the transfer unit 4, such that the second electronic component 20 may have the direction of the inner conductors 12 same as that of the first electronic component 10.

In this case, the magnetic field providing unit 5 may include a permanent magnet or a solenoid electromagnet.

In addition, the electronic component aligning device 1 according to the exemplary embodiment of the present invention may further include a pickup transfer unit 8 picking up the electronic component having 10 passed through the magnetic field providing unit 5, and transferring the electronic component 10 from the transfer unit 4 to an electronic component packaging body 40

The pickup transfer unit 8 may be any unit transferring the electronic components to the electronic component packaging body 40 without changing the direction of the inner conductors 12 in the electronic component 10.

### Electronic Component Packaging Body

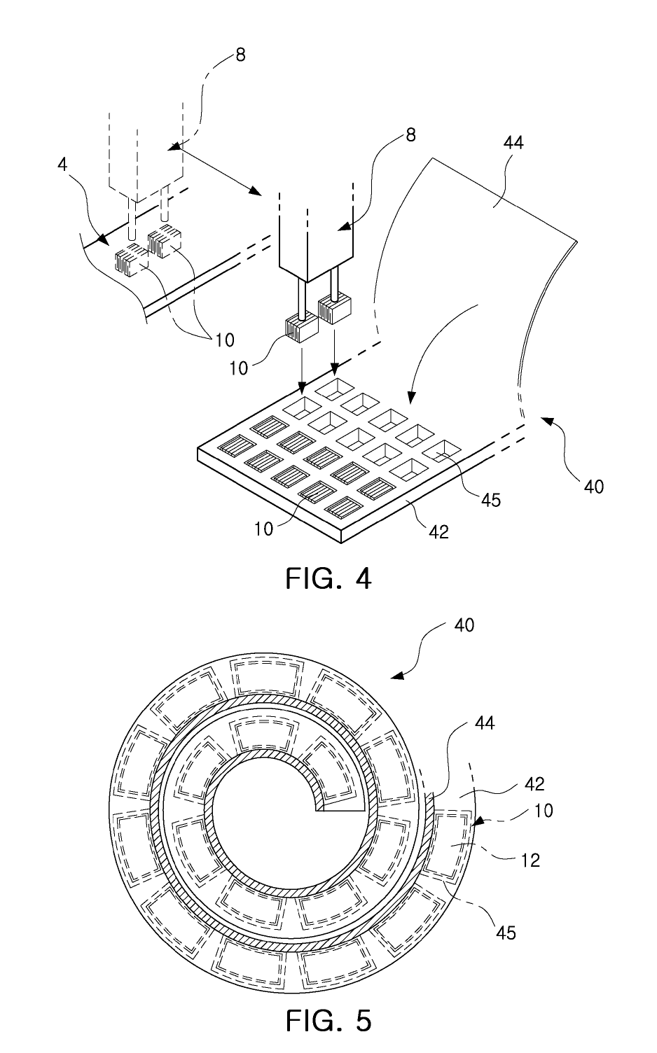

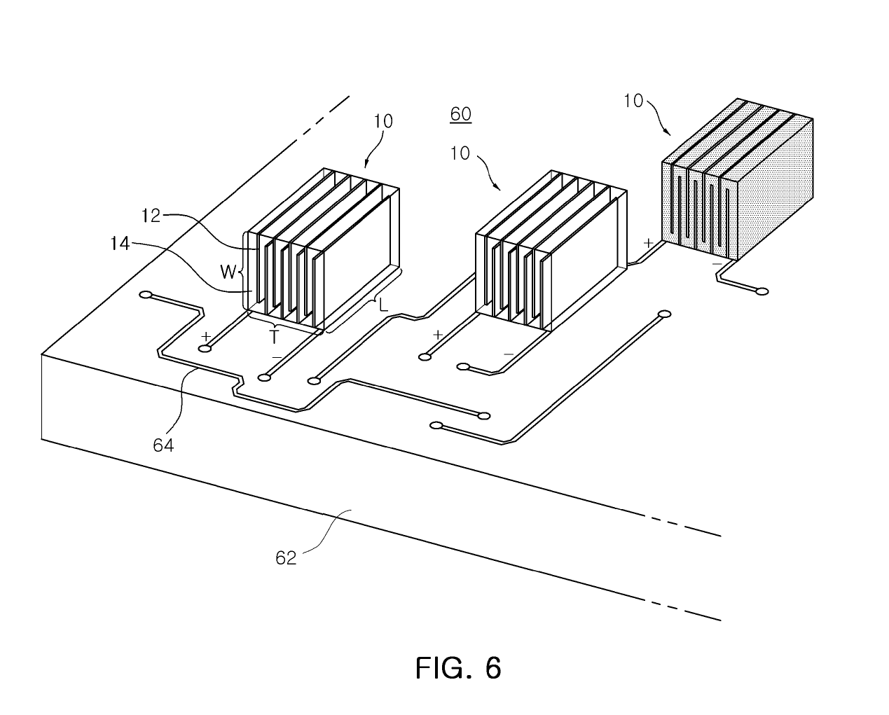

FIG. 4 is a perspective view schematically showing that electronic components are aligned and mounted in a packaging body according to an exemplary embodiment of the present invention. FIG. 5 is a diagram schematically showing a roll-type packaging body according to another exemplary embodiment of the present invention.

Referring to FIG. 4, the electronic component packaging body 40 according to the exemplary embodiment of the present invention may be configured to include a packaging sheet 42 in which a receiving part 45 receiving the electronic component 10 is formed.

The receiving part 45 of the packaging sheet 42 has a shape corresponding to the electronic component 10 and the electronic component 10 may be moved by the pickup transfer unit 8 in such a manner that the inner conductors 12 are vertically disposed with relation to the bottom surface of the receiving part 45.

The electronic component packaging body 40 may be configured to further include a packaging layer 44 covering the packaging sheet 42 in which the electronic component 10 having therein, the inner conductors 12 vertically disposed with relation to the bottom surface of the receiving part 45 is received.

FIG. 5 shows an electronic component packaging body having a shape wound in the form of a roll, which may be formed by continuously winding the electronic component packaging body 40 according to the exemplary embodiment of FIG. 4 by a collecting roll (not shown).

### Electronic Component Mounting Board

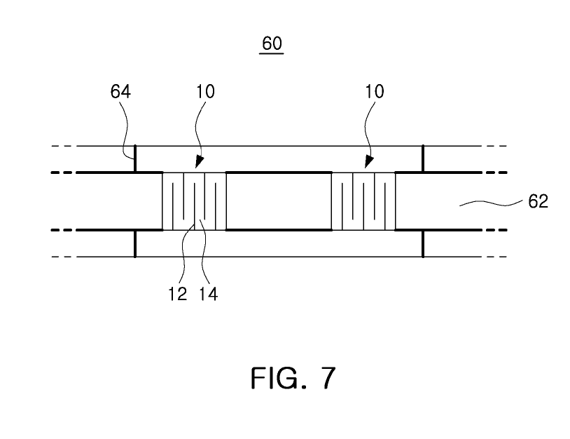

FIG. 6 is a perspective view schematically showing an electronic component mounting board on which aligned electronic components are mounted according to an exemplary embodiment of the present invention; and FIG. 7 is a cross sectional view schematically showing an electronic component mounting board on which aligned electronic components are buried and mounted according to another exemplary embodiment of the present invention.

Referring to FIG. 6, an electronic component mounting board 60 may be configured to include a printed circuit board 62 on which the electronic component 10 is mounted.

The electrode component 10 having therein, the inner conductors 12 vertically disposed with relation to the mounting surface of the printed circuit board 62 may be mounted on the printed circuit board 62. The electronic component 10 is mounted on wires 64 formed on the printed circuit board 62.

In the electronic component packaging body 40 in which the electronic component 10 aligned by the above-mentioned electronic component aligning device 1 is received, the inner conductors 12 in the electronic component 10 may be moved to the printed circuit board 62 without changing the direction thereof.

In this case, a plurality of electronic components 10 having the same width W and height T may be mounted on the printed circuit board 62 of the electronic component mounting board 60. In this case, the inner conductors 12 in all of the electronic components 10 are disposed in such a manner as to be vertical to the mounting surface of the printed circuit board 62, such that the inner conductors are mounted in a direction parallel with the surface of the printed circuit board, thereby allowing the occurrence of acoustic noise to be remarkably reduced.

Referring to FIG. 7, the electronic component 10 may be buried in the printed circuit board 62. In this case, the inner conductors of the electronic component 10 may be mounted in the printed circuit board 62 in such a manner to be vertical to the burying surface of the printed circuit board 62.

As set forth above, according to the electronic component aligning device, the electronic component packaging body, and the electronic component mounting board according to the exemplary embodiments of the present invention, electronic components could be mounted on the printed circuit board, the electronic components having therein, inner conductors aligned vertically to the printed circuit board.

In particular, according to the exemplary embodiments of the present invention, the reliability of products could be improved by mounting the inner conductors on the printed circuit board in the state in which the inner conductors are aligned vertically in relation to the printed circuit board, even in the case in which the electronic components having the same width W and height T, which are difficult to discriminate appearances thereof, are mounted on the printed circuit board.

Further, according to the exemplary embodiments of the present invention, acoustic noise occurring from the printed circuit board could be remarkably reduced by aligning the inner conductors on the printed circuit board in such a manner as to be vertical thereto.

While the present invention has been shown and described in connection with the exemplary embodiments, it will be apparent to those skilled in the art that modification and variation can be made without departing from the spirit and scope of the invention as defined by the appended claims.

What is claimed is:

1. An electronic component aligning device, comprising:
a tray provided with electronic components formed thereon by stacking dielectric sheets on which inner conductors are formed;
a transfer unit continuously transferring the electronic components moved from the tray; and
a magnetic field providing unit providing a magnetic field to the electronic components moved from the transfer unit to align the inner conductors in a direction in which the magnetic field and magnetic resistance are reduced.

2. The electronic component aligning device of claim 1, wherein the magnetic field flows between the inner conductors having the dielectric sheets interposed therebetween.

3. The electronic component aligning device of claim 1, wherein the inner conductors in the electronic components having passed through the magnetic field providing unit are vertically disposed with relation to a moving direction of the transfer unit.

4. The electronic component aligning device of claim 1, wherein the magnetic field providing unit includes a permanent magnet and a solenoid electromagnet.

5. The electronic component aligning device of claim 1, wherein the electronic components have the same width W and height H.

6. The electronic component aligning device of claim 1, further comprising a pickup transfer unit picking up the electronic components having passed through the magnetic field providing unit and transferring the electronic components from the transfer unit to an electronic component packaging body.

7. The electronic component aligning device of claim 1, wherein the electronic components include a multilayer ceramic capacitor, an inductor, a line filter, or a varistor.

8. An electronic component packaging body, comprising:
electronic components formed by stacking dielectric sheets on which inner conductors are formed; and
a packaging sheet formed with a receiving part in which the electronic components are received,
wherein the inner conductors are vertically disposed with relation to the bottom surface of the receiving part by using the electronic components aligned by the electronic component aligning device of any one of claims 1 to 6.

9. The electronic component packaging body of claim 8, further comprising a packaging layer coupled with the packaging sheet and covering the electronic components.

10. An electronic component mounting board, comprising:
electronic components formed by stacking dielectric sheets on which inner conductors are formed; and
a printed circuit board on which the electronic components are mounted,
wherein the inner conductors are vertically disposed with relation with a mounting surface of the printed circuit board by transferring the electronic components within the electronic component packaging body of claim 6, without changing the direction thereof.

11. The electronic component mounting board of claim 10, wherein the electronic components are buried in the printed circuit board.

12. The electronic component mounting board of claim 10, wherein the electronic components are provided in plural, each of the electronic components having the same width W and height T.

13. An electronic component mounting board, comprising:
a plurality of electronic components each having the same width W and height T and formed by stacking dielectric sheets on which inner conductors are formed; and
a printed circuit board having the electronic components thereon and having the inner conductors thereon in such a manner that all of the inner conductors in the plurality of electronic components are arranged in a vertical direction with relation to the mounting surface of the printed circuit board.

14. The electronic component mounting board of claim 13, wherein the electronic components are buried in the printed circuit board.
